(19) United States
(12) Patent Application Publication
(10) Pub. No.: US 2026/0231474 A1
(43) Pub. Date: Aug. 6, 2026

(54) DISPLAY DEVICE

(71) Applicant: Sharp Kabushiki Kaisha, Osaka (JP)

(72) Inventors: Hideki KITAGAWA, Sakai City (JP); Yoshihito HARA, Sakai City (JP); Masaki MAEDA, Sakai City (JP); Jun NISHIMURA, Sakai City (JP); Yoshiharu HIRATA, Sakai City (JP); Kengo HARA, Sakai City (JP)

(21) Appl. No.: 19/437,420

(22) Filed: Dec. 31, 2025

(30) Foreign Application Priority Data
Feb. 6, 2025 (JP) 2025-018157

(51) Int. Cl. H10D 30/67; H10K 59/131; H10K 59/80

(52) U.S. Cl. CPC H10D 30/6737; H10D 30/6755; H10K 59/131; H10K 59/80518; H10K 59/80524; H10K 59/871

(57) ABSTRACT

A display device includes a base substrate; a TFT layer provided on the base substrate and including a first metal film, a first inorganic insulating film, a second metal film, a first organic insulating film, a third metal film, and a second organic insulating film that are sequentially stacked; and a light-emitting element layer provided on the TFT layer. The third metal film includes a titanium-based metal film, an aluminum-based metal film, and a titanium-based metal film that are sequentially stacked.

### BACKGROUND

### 1. Field

The present disclosure relates to a display device.

### 2. Description of the Related Art

In recent years, self-emissive organic electroluminescence (EL) display devices employing organic EL elements have attracted attention as potential alternatives to liquid crystal display devices. Such an organic EL display device includes, for example, a base substrate; a thin film transistor (TFT) layer provided on the base substrate and having TFTs arranged therein; an organic EL element layer provided on the TFT layer and having a plurality of organic EL elements arranged corresponding to a plurality of subpixels constituting a display region; and a sealing film provided on the organic EL element layer.

For example, International Publication No. 2023/105569 discloses an organic EL display device in which the TFT layer includes a first metal layer containing a copper film; a plurality of pixel electrodes included in the organic EL element layer are formed of a second metal layer containing a silver film, a plurality of terminals provided in a terminal portion is formed of the same material and in the same layer as the first metal layer, and a protective layer formed of a transparent conductive film is provided on each terminal.

However, the organic EL display device as disclosed in International Publication No. 2023/105569 described above, for example, employs a copper film in the conductive layers such as wirings and electrodes in the TFT layer, the copper film having lower electrical resistance than an aluminum film. In such an organic EL display device, instead of directly forming an organic insulating film on the copper film, an inorganic insulating film is to be interposed between the copper film and the organic insulating film in order to suppress corrosion of the copper film due to moisture or the like contained in the organic insulating film. In this case, differing pattern shapes between the inorganic insulating film and the organic insulating film lead to an additional photomask dedicated to patterning the inorganic insulating film, which increases the total number of photomasks and leaves room for improvement.

It is desirable to reduce the number of photomasks used to form a TFT layer.

### SUMMARY

According to an aspect of the disclosure, there is provided a display device including a base substrate; a thin film transistor layer provided on the base substrate, the thin film transistor layer including a first metal film, a first inorganic insulating film, a second metal film, a first organic insulating film, a third metal film, and a second organic insulating film that are sequentially stacked; and a light-emitting element layer provided on the thin film transistor layer. The third metal film includes a titanium-based metal film, an aluminum-based metal film, and a titanium-based metal film that are sequentially stacked.

### BRIEF DESCRIPTION OF THE DRAWINGS

FIG. 1 is a plan view illustrating a schematic configuration of an organic EL display device according to a first embodiment of the present disclosure;

FIG. 2 is a plan view of a display region of the organic EL display device according to the first embodiment of the present disclosure;

FIG. 3 is a cross-sectional view of the display region of the organic EL display device according to the first embodiment of the present disclosure;

FIG. 4 is a cross-sectional view of a terminal portion of the organic EL display device according to the first embodiment of the present disclosure;

FIG. 5 is an equivalent circuit diagram of a TFT layer included in the organic EL display device according to the first embodiment of the present disclosure;

FIG. 6 is a cross-sectional view illustrating an organic EL layer included in the organic EL display device according to the first embodiment of the present disclosure;

FIG. 7 is a cross-sectional view of a display region of an organic EL display device according to a second embodiment of the present disclosure, corresponding to FIG. 3; and

FIG. 8 is a cross-sectional view of a terminal portion of the organic EL display device according to the second embodiment of the present disclosure, corresponding to FIG. 4.

### DESCRIPTION OF THE EMBODIMENTS

Hereinafter, embodiments of the present disclosure will be described in detail with reference to the drawings. It is noted that the present disclosure is not limited to the embodiments described below.

### First Embodiment

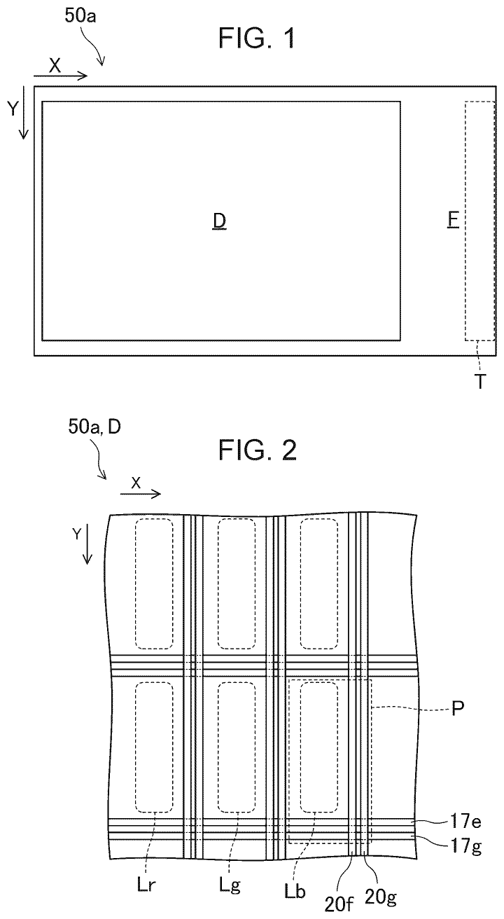

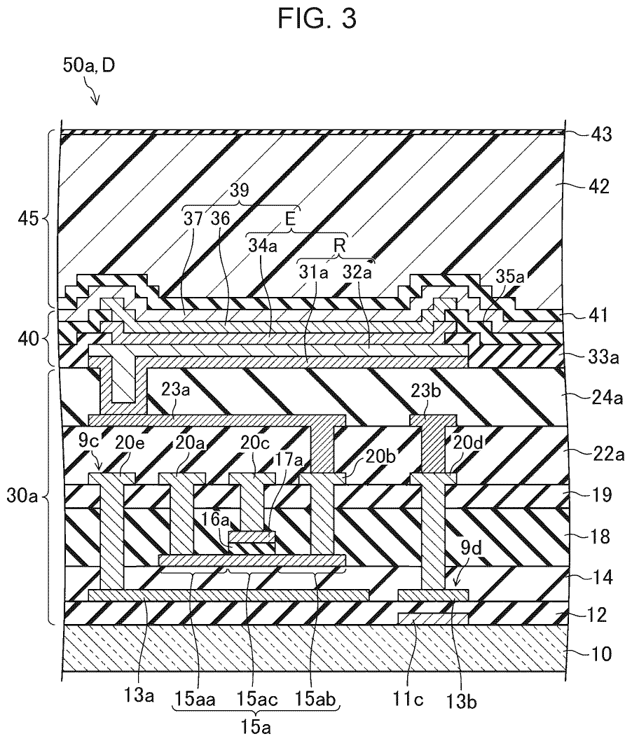

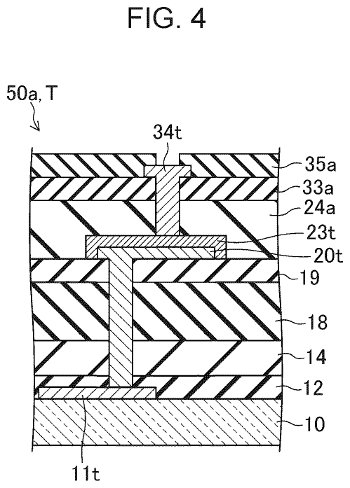

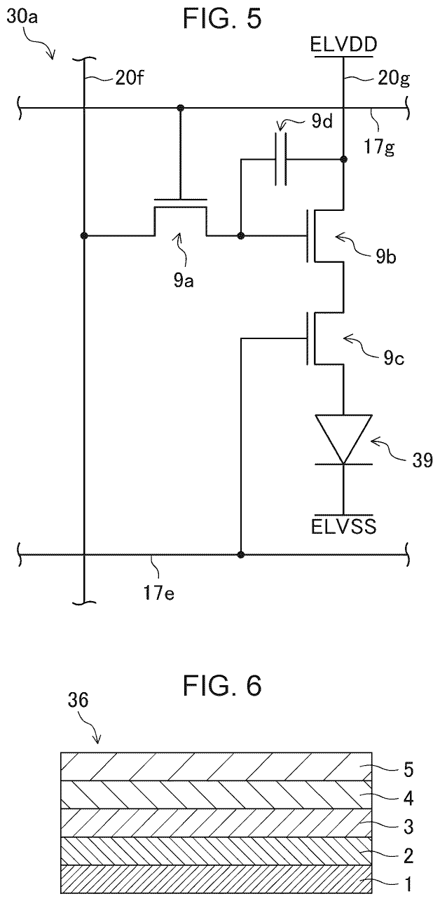

FIGS. 1 to 6 illustrate a first embodiment of a display device according to the present disclosure. Here, FIG. 1 is a plan view illustrating a schematic configuration of an organic EL display device 50a of the present embodiment. FIGS. 2 and 3 are a plan view and a cross-sectional view, respectively, of a display region of the organic EL display device 50a. FIG. 4 is a cross-sectional view of a terminal portion T of the organic EL display device 50a. FIG. 5 is an equivalent circuit diagram of a TFT layer 30a included in the organic EL display device 50a. FIG. 6 is a cross-sectional view illustrating an organic EL layer 36 included in the organic EL display device 50a.

As illustrated in FIG. 1, the organic EL display device 50a includes, for example, a display region D configured to display an image and provided in a rectangular shape, and a frame region F provided in a frame shape around the display region D. In the present embodiment, the display region D is exemplified as having a rectangular shape; however, the term “rectangular shape” herein also encompasses substantially rectangular shapes such as those having an arcuate side, an arcuate corner, or a side partially provided with a cutout.

As illustrated in FIG. 2, a plurality of subpixels P is arranged in a matrix within the display region D. In the display region D, as illustrated in FIG. 2, subpixels P each having a red light-emitting region Lr for displaying red, subpixels P each having a green light-emitting region Lg for displaying green, and subpixels P each having a blue light-emitting region Lb for displaying blue are provided adjacent to each other. In the display region D, for example, one pixel is constituted of three adjacent subpixels P having the red light-emitting region Lr, the green light-emitting region Lg, and the blue light-emitting region Lb.

At a positive-side end of the frame region F in the X-direction in FIG. 1, the terminal portion T is provided to extend in one direction (in the Y-direction in FIG. 1). Here, in the organic EL display device 50a, display wirings including gate lines 17g, light emission control lines 17e, source lines 20f, and power supply lines 20g, all of which are provided in the display region D and will be described later, are drawn out toward the terminal portion T.

As illustrated in FIG. 3, the organic EL display device 50a may include a glass substrate 10 provided as the base substrate, the TFT layer 30a provided on the glass substrate 10, an organic EL element layer 40 provided on the TFT layer 30a as the light-emitting element layer, and a sealing film 45 provided on the organic EL element layer 40.

The glass substrate 10 has, for example, a thickness of about 0.1 mm to about 0.5 mm.

As illustrated in FIG. 3, the TFT layer 30a includes a plurality of first TFTs 9a (see FIG. 5), a plurality of second TFTs 9b (see FIG. 5), a plurality of third TFTs 9c, and a plurality of capacitors 9d, all provided on the glass substrate 10; and a first planarization film 22a and a second planarization film 24a that are sequentially provided on each first TFT 9a, each second TFT 9b, each third TFT 9c, and each capacitor 9d.

As illustrated in FIG. 3, the TFT layer 30a has a fourth metal film, a base insulating film 12, a fifth metal film, a first gate insulating film 14, a semiconductor film, a second gate insulating film (third inorganic insulating film) 16a, a first metal film, a first interlayer insulating film (first inorganic insulating film) 18, a second interlayer insulating film (first inorganic insulating film) 19, a second metal film, the first planarization film (first organic insulating film) 22a, a third metal film, and the second planarization film (second organic insulating film) 24a, all of which are sequentially stacked on the glass substrate 10. The fourth metal film forms a first capacitor electrode 11c and the like as will be described later. The fifth metal film forms a first gate electrode 13a and the like as will be described later. The semiconductor film forms a semiconductor layer 15a and the like as will be described later. The first metal film forms a second gate electrode 17a and the like as will be described later. The second metal film forms a source electrode 20a and the like as will be described later. The third metal film forms a relay electrode 23a and the like as will be described later. Here, the base insulating film 12, the first gate insulating film 14, the second gate insulating film 16a, the first interlayer insulating film 18, and the second interlayer insulating film 19 are each formed of a single-layer film made of an inorganic insulating film such as a silicon nitride film, a silicon oxide film, or a silicon oxynitride film, for example, or a multilayer film thereof. The side of the first gate insulating film 14 facing the semiconductor layer 15a and the side of the second gate insulating film 16a facing the semiconductor layer 15a are each formed, for example, of a silicon oxide film. Further, each of the second metal film and the third metal film is formed by sequentially stacking, for example, a titanium-based metal film made of titanium or a titanium alloy, an aluminum-based metal film made of aluminum or an aluminum alloy, and a titanium-based metal film made of titanium or a titanium alloy.

As illustrated in FIG. 2, the gate lines 17g are provided in the TFT layer 30a so as to extend in parallel to each other in the X-direction in the drawing. In addition, as illustrated in FIG. 2, the light emission control lines 17e are provided in the TFT layer 30a so as to extend in parallel to each other in the X-direction in the drawing. Here, each light emission control line 17e is provided adjacent to a corresponding gate line 17g, as illustrated in FIG. 2. Furthermore, as illustrated in FIG. 2, the source lines 20f are provided in the TFT layer 30a so as to extend in parallel to each other in the Y-direction in the drawing. Moreover, as illustrated in FIG. 2, the power supply lines 20g are provided in the TFT layer 30a so as to extend in parallel to each other in the Y-direction in the drawing. Each power supply line 20g is provided adjacent to a corresponding source line 20f, as illustrated in FIG. 2. Here, each gate line 17g and each light emission control line 17e are formed of the first metal film, while each source line 20f and each power supply line 20g are formed of the second metal film. As illustrated in FIG. 5, each subpixel P in the TFT layer 30a is provided with the first TFT 9a, the second TFT 9b, the third TFT 9c, and the capacitor 9d.

As illustrated in FIG. 5, the first TFT 9a is electrically connected to the corresponding gate line 17g and source line 20f and to the second TFT 9b in each subpixel P. The first TFT 9a has substantially the same structure as the third TFT 9c described later, and thus a detailed description of its structure is omitted herein.

As illustrated in FIG. 5, the second TFT 9b is electrically connected to the corresponding first TFT 9a and power supply line 20g and to the third TFT 9c in each subpixel P. The second TFT 9b has substantially the same structure as the third TFT 9c, and thus a detailed description of its structure is omitted.

As illustrated in FIG. 5, in each subpixel P, the third TFT 9c is electrically connected to the corresponding second TFT 9b, and a first electrode E and the light emission control line 17e, both of which are included in an organic EL element 39 described later. As illustrated in FIG. 3, the third TFT 9c includes the semiconductor layer 15a; the first gate electrode 13a provided on the glass substrate 10 side of the semiconductor layer 15a with the first gate insulating film 14 interposed therebetween; the second gate electrode 17a provided on the opposite side of the semiconductor layer 15a from the glass substrate 10 with the second gate insulating film 16a interposed therebetween; and the source electrode 20a and the drain electrode 20b provided on the second interlayer insulating film 19 so as to be spaced apart from each other.

The semiconductor layer 15a is formed of, for example, a semiconductor film made of an oxide semiconductor such as an In—Ga—Zn—O-based semiconductor. As illustrated in FIG. 3, the semiconductor layer 15a includes a source region 15aa and a drain region 15ab that are defined so as to be spaced apart from each other, and a channel region 15ac defined between the source region 15aa and the drain region 15ab. Here, the In—Ga—Zn—O-based semiconductor is a ternary oxide of indium (In), gallium (Ga), and zinc (Zn), wherein the ratio (composition ratio) of In, Ga, and Zn is not particularly limited. The In—Ga—Zn—O-based semiconductor may be amorphous or crystalline. As one example of the crystalline In—Ga—Zn—O-based semiconductor, a crystalline In—Ga—Zn—O-based semiconductor having its c-axis oriented substantially perpendicular to the layer plane is proposed. Instead of the In—Ga—Zn—O-based semiconductor, the semiconductor film may contain other oxide semiconductors. Examples of other oxide semiconductors include, but are not limited to, In—Sn—Zn—O-based semiconductors (e.g., In₂O₃-SnO₂-ZnO; InSnZnO). Here, the In—Sn—Zn—O—based semiconductor is a ternary oxide of indium (In), tin (Sn), and zinc (Zn). Furthermore, examples of other oxide semiconductors may include, but are not limited to, In—Al—Zn—O-based semiconductors, In—Al—Sn—Zn—O-based semiconductors, Zn—O-based semiconductors, In—Zn—O-based semiconductors, Zn—Ti—Obased semiconductors, Cd—Ge—O-based semiconductors, Cd—Pb—O-based semiconductors, CdO (cadmium oxide), Mg—Zn—O-based semiconductors, In—Ga—Sn—O-based semiconductors, In—Ga—O-based semiconductors, Zr—In—Zn—O-based semiconductors, Hf—In—Zn—O-based semiconductors, Al—Ga—Zn—O-based semiconductors, Ga—Zn—O-based semiconductors, In—Ga—Zn—Sn—O-based semiconductors, InGaO₃(ZnO)₅, magnesium zinc oxides (MgₓZn₁₋ₓO), and cadmium zinc oxides (CdₓZn₁₋ₓO). The Zn—O-based semiconductor that can be used may be amorphous (noncrystalline), polycrystalline, or microcrystalline ZnO, the microcrystalline ZnO being composed of a combination of noncrystalline and polycrystalline ZnO, and the ZnO having one or more impurity elements selected from Group 1, Group 13, Group 14, Group 15, and Group 17 elements added thereto, or having no impurity elements.

As illustrated in FIG. 3, the first gate electrode 13a is provided to overlap the semiconductor layer 15a, and is configured, for example, to control characteristics such as an S value (subthreshold swing) of the third TFT 9c. Here, as illustrated in FIG. 3, the first gate electrode 13a is electrically connected to a wiring layer 20e through a contact hole formed in the first gate insulating film 14, the first interlayer insulating film 18, and the second interlayer insulating film 19. The wiring layer 20e, the source electrode 20a, a drain electrode 20b, a wiring layer 20c to be described later, a wiring layer 20d, and a first terminal layer 20t may be formed of the second metal film, as in the source line 20f and the like.

As illustrated in FIG. 3, the second gate electrode 17a is provided to overlap the channel region 15ac of the semiconductor layer 15a, and is configured to control the conduction between the source region 15aa and the drain region 15ab of the semiconductor layer 15a. Here, as illustrated in FIG. 3, the second gate electrode 17a is electrically connected to the wiring layer 20c through a contact hole formed in the first interlayer insulating film 18 and the second interlayer insulating film 19. The second gate electrode 17a is formed of the first metal film, as in the gate line 17g and the like.

As illustrated in FIG. 3, the source electrode 20a and the drain electrode 20b are electrically connected to the source region 15aa and the drain region 15ab of the semiconductor layer 15a through contact holes formed in the first interlayer insulating film 18 and the second interlayer insulating film 19, respectively. Here, as illustrated in FIG. 3, the drain electrode 20b is electrically connected to the relay electrode 23a that is formed of the third metal film, through a contact hole formed in the first planarization film 22a.

In the present embodiment, the first TFT 9a, the second TFT 9b, and the third TFT 9c are exemplified as being of a double-gate type. However, the first TFT 9a, the second TFT 9b, and the third TFT 9c may alternatively be of a top-gate type or bottom-gate type. In addition, in the present embodiment, the first TFT 9a, the second TFT 9b, and the third TFT 9c are exemplified as each including the semiconductor layer 15a made of an oxide semiconductor; however, the semiconductor layer 15a may instead be made of polysilicon, such as low temperature polysilicon (LTPS). Furthermore, the TFT layer 30a may have a hybrid structure including a TFT having a semiconductor layer formed of polysilicon and a TFT having a semiconductor layer formed of an oxide semiconductor.

As illustrated in FIG. 5, the capacitor 9d is electrically connected to the corresponding first TFT 9a and the power supply line 20g in each subpixel P. As illustrated in FIG. 3, the capacitor 9d includes the first capacitor electrode 11c formed of the fourth metal film, a second capacitor electrode 13b formed of the fifth metal film, and the base insulating film 12 provided between the first capacitor electrode 11c and the second capacitor electrode 13b. Here, as illustrated in FIG. 3, the second capacitor electrode 13b is electrically connected to the wiring layer 20d formed of the first metal film through a contact hole formed in the first gate insulating film 14, the first interlayer insulating film 18, and the second interlayer insulating film 19. As illustrated in FIG. 3, the wiring layer 20d is electrically connected to a wiring layer 23b formed of the third metal film through a contact hole formed in the first planarization film 22a. The wiring layers 20d and 23b are electrically connected to the corresponding power supply line 20g.

The first planarization film 22a and the second planarization film 24a have flat surfaces in the display region D and are formed, for example, of an organic resin material such as a polyimide resin or an acrylic resin, or of a polysiloxane-based spin on glass (SOG) material or the like.

As illustrated in FIG. 3, the organic EL element layer 40 may include a plurality of first electrodes E, a plurality of organic EL layers 36, and a common second electrode 37 that are sequentially stacked, corresponding to a plurality of subpixels P. In each subpixel P, as illustrated in FIG. 3, the first electrode E, the organic EL layer 36, and the second electrode 37 constitute the organic EL element 39. In the organic EL element layer 40, a plurality of organic EL elements 39 corresponding to the plurality of subpixels P are arranged in a matrix.

The first electrodes E are provided on the second planarization film 24a in a matrix while corresponding to the respective plurality of subpixels P. As illustrated in FIG. 3, each first electrode E is electrically connected to the drain electrode 20b of the corresponding third TFT 9c through a contact hole formed in the second planarization film 24a, and a contact hole formed in the relay electrode 23a and the first planarization film 22a. As illustrated in FIG. 3, each first electrode E may include a reflective electrode R provided on the second planarization film 24a and a transparent electrode 34a provided on the reflective electrode R.

As illustrated in FIG. 3, the reflective electrode R includes a transparent conductive layer 31a provided on the second planarization film 24a and a metal layer 32a provided on the transparent conductive layer 31a. Here, as illustrated in FIG. 3, the peripheral edge portion of the reflective electrode R may be covered with a first edge cover 33a provided in a lattice pattern over the entire display region D. The first edge cover 33a is formed of an inorganic insulating film, for example, a single-layer film made of silicon nitride, silicon oxide, silicon oxynitride, or the like, or a multilayer film thereof.

The transparent conductive layer 31a is formed of a transparent conductive film such as an indium tin oxide (ITO) film and has light transmittance.

The metal layer 32a is formed of a metal film such as a silver film or a silver alloy film and has light reflectivity.

The transparent electrode 34a functions to inject holes into the organic EL layer 36. The transparent electrode 34a may be formed of a material having a large work function in order to improve hole injection efficiency into the organic EL layer 36. Here, the transparent electrode 34a is formed, for example, of a transparent conductive film such as an ITO film and has light transmittance. As illustrated in FIG. 3, the peripheral edge portion of the transparent electrode 34a may be covered with a second edge cover 35a that is provided in a lattice pattern over the entire display region D. The second edge cover 35a is formed of an inorganic insulating film, for example, a single-layer made of silicon nitride, silicon oxide, silicon oxynitride, or the like, or a multilayer film thereof.

The organic EL layer 36 is provided as a light-emitting functional layer and, as illustrated in FIG. 6, includes a hole injection layer 1, a hole transport layer 2, a light-emitting layer 3, an electron transport layer 4, and an electron injection layer 5, all of which are sequentially stacked on the transparent electrode 34a. In the present embodiment, each of the plurality of light-emitting functional layers is exemplified as being composed of the organic EL layer 36, but at least one of the plurality of light-emitting functional layers may be the organic EL layer 36.

The hole injection layer 1, also referred to as an anode buffer layer, functions to bring the energy levels of the first electrode E and the organic EL layer 36 closer to each other and to improve the hole injection efficiency from the first electrode E into the organic EL layer 36. Here, examples of materials constituting the hole injection layer 1 include, but are not limited to, polyarylalkane derivatives, pyrazoline derivatives, phenylenediamine derivatives, oxazole derivatives, styrylanthracene derivatives, fluorenone derivatives, hydrazone derivatives, stilbene derivatives, and the like.

The hole transport layer 2 functions to improve the transport efficiency of holes from the first electrode E to the organic EL layer 36. Here, examples of materials constituting the hole transport layer 2 include, but are not limited to, triphenylamine derivatives, porphyrin derivatives, aromatic tertiary amine compounds, styrylamine derivatives, polyvinylcarbazole, poly-p-phenylenevinylene, polysilane, polyarylalkane derivatives, pyrazoline derivatives, pyrazolone derivatives, phenylenediamine derivatives, arylamine derivatives, amine-substituted chalcone derivatives, fluorenone derivatives, hydrazone derivatives, hydrogenated amorphous silicon, hydrogenated amorphous silicon carbide, zinc sulfide, zinc selenide, and the like.

The light-emitting layer 3 is a region in which holes and electrons are injected from the first electrode E and the second electrode 37, respectively, and then recombine together when a voltage is applied between the first electrode E and the second electrode 37. Here, the light-emitting layer 3 is formed of a material having high luminous efficiency. Examples of materials constituting the light-emitting layer 3 include, but are not limited to, metal oxinoid compounds [8-hydroxyquinoline metal complexes], naphthalene derivatives, anthracene derivatives, diphenylethylene derivatives, vinylacetone derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bis-styrylbenzene derivatives, tris-styrylbenzene derivatives, perylene derivatives, perinone derivatives, aminopyrene derivatives, pyridine derivatives, rhodamine derivatives, acridine derivatives, phenoxazone, quinacridone derivatives, rubrene, poly-p-phenylenevinylene, polysilane, and the like.

The electron transport layer 4 functions to efficiently move electrons to the light-emitting layer 3. Examples of materials constituting the electron transport layer 4 include, but are not limited to, imidazole derivatives, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, metal oxinoid compounds, and the like.

The electron injection layer 5 functions to bring the energy levels of the second electrode 37 and the organic EL layer 36 closer to each other, thereby improving the efficiency of electron injection from the second electrode 37 into the organic EL layer 36. This function allows the driving voltage of the organic EL element 39 to be reduced. The electron injection layer 5 is also referred to as a cathode buffer layer. Examples of materials constituting the electron injection layer 5 include, but are not limited to, inorganic alkali compounds such as lithium fluoride (LiF), magnesium fluoride (MgF₂), calcium fluoride (CaF₂), strontium fluoride (SrF₂), and barium fluoride (BaF₂), as well as aluminum oxide (Al₂O₃) and strontium oxide (SrO).

The second electrode 37 is provided so as to be common among the plurality of subpixels P over the plurality of organic EL layers 36, that is, so as to cover each organic EL layer 36 and the second edge cover 35a as illustrated in FIG. 3. The second electrode 37 functions to inject electrons into the organic EL layer 36. The second electrode 37 may be formed of a material having a small work function in order to improve the electron injection efficiency into the organic EL layer 36. Here, the second electrode 37 is formed, for example, of a transparent conductive film such as an ITO film or an IZO film, or an ultrathin metal film such as a MgAg film, and has light transmittance.

As illustrated in FIG. 3, the sealing film 45 is provided so as to cover the second electrode 37. The sealing film 45 includes, in order, a first inorganic sealing film 41, an organic sealing film 42, and a second inorganic sealing film 43 that are sequentially stacked on the second electrode 37. The sealing film 45 functions to protect the organic EL layer 36 of the organic EL element 39 from moisture and oxygen.

The first inorganic sealing film 41 and the second inorganic sealing film 43 are each formed of an inorganic insulating film such as a silicon nitride film, a silicon oxide film, or a silicon oxynitride film.

The organic sealing film 42 is formed of an organic resin material such as an acrylic resin, an epoxy resin, a silicone resin, a polyurea resin, a parylene resin, a polyimide resin, or a polyamide resin.

Further, the organic EL display device 50a includes a plurality of first terminal layers 20t (see FIG. 4) at the terminal portion T in the frame region F, each first terminal layer 20t being provided along the extending direction (Y-direction in FIG. 1) of the terminal portion T and formed of the second metal film. At the terminal portion T, as illustrated in FIG. 4, the second planarization film 24a, but not the first planarization film 22a, is provided.

As illustrated in FIG. 4, each first terminal layer 20t may be covered with a second terminal layer 23t formed of the third metal film. As illustrated in FIG. 4, each first terminal layer 20t is electrically connected to a fourth terminal layer 11t formed of the fourth metal film through a contact hole formed in the base insulating film 12, the first gate insulating film 14, the first interlayer insulating film 18, and the second interlayer insulating film 19. Each fourth terminal layer 11t is electrically connected, for example, to display wirings such as the gate line 17g, the light emission control line 17e, the source line 20f, and the power supply lines 20g. As illustrated in FIG. 4, each second terminal layer 23t may be electrically connected to a third terminal layer 34t formed of the same material and in the same layer as the transparent electrode 34a, through a contact hole formed in the second planarization film 24a and the first edge cover 33a. As illustrated in FIG. 4, here, at the terminal portion T, the second planarization film 24a, the first edge cover 33a, and the second edge cover 35a may be sequentially stacked on each second terminal layer 23t, with the peripheral edge portion of each third terminal layer 34t covered with the second edge cover 35a, allowing a part of the third terminal layer 34t to be exposed from the second edge cover 35a.

In each subpixel P of the organic EL display device 50a with the above configuration, when a gate signal is input to the first TFT 9a via the gate line 17g, the first TFT 9a is turned on, causing a predetermined voltage corresponding to a source signal to be applied to the gate electrode of the second TFT 9b and the capacitor 9d via the source line 20f. When a light emission control signal is input to the third TFT 9c via the light emission control line 17e, the third TFT 9c is turned on, causing a current corresponding to the gate voltage of the second TFT 9b to be supplied from the power supply line 20g to the organic EL layer 36 of the organic EL element 39. As a result, the light-emitting layer 3 of the organic EL layer 36 emits light to perform image display. In the organic EL display device 50a, even when the first TFT 9a is turned off, the gate voltage of the second TFT 9b is held by the capacitor 9d, so that light emission by the light-emitting layer 3 in each subpixel P is maintained until the gate signal of the next frame is input.

Next, a method for manufacturing the organic EL display device 50a of the present embodiment will be described. The method for manufacturing the organic EL display device 50a of the present embodiment includes a TFT layer forming step, an organic EL element layer forming step, and a sealing film forming step.

### TFT Layer Forming Step

First, for example, a copper film (having a thickness of about 300 nm) or the like is deposited by sputtering on the glass substrate 10 to form the fourth metal film. Then, the fourth metal film is patterned to form the first capacitor electrodes 11c, the fourth terminal layers 11t, and the like.

Subsequently, for example, a silicon nitride film (having a thickness of about 150 nm) or the like is deposited by plasma chemical vapor deposition (CVD) on the surface of the substrate on which the first capacitor electrodes 11c and the like are formed, thereby forming the base insulating film 12.

Thereafter, for example, a titanium film (having a thickness of about 20 nm) and a copper film (having a thickness of about 300 nm) are sequentially deposited by sputtering on the surface of the substrate on which the base insulating film 12 is formed, thereby forming the fifth metal film. The fifth metal film is then patterned to form the first gate electrode 13a, the second capacitor electrode 13b, and the like.

Further, for example, a silicon nitride film (having a thickness of about 100 nm) and a silicon oxide film (having a thickness of about 200 nm) are sequentially deposited by plasma CVD on the surface of the substrate on which the first gate electrodes 13a and the like are formed, thereby forming the first gate insulating film 14.

Subsequently, for example, a semiconductor film made of InGaZnO₄ (having a thickness of about 50 nm) or the like is deposited by sputtering on the surface of the substrate on which the first gate insulating film 14 is formed, followed by patterning the semiconductor film, thereby forming the semiconductor layer 15a and the like.

Thereafter, a third inorganic insulating film, such as a silicon oxide film (having a thickness of about 200 nm), for example, is deposited by plasma CVD on the surface of the substrate on which the semiconductor layers 15a and the like are formed. Subsequently, for example, a copper film (having a thickness of about 300 nm) is deposited thereon by sputtering to form a first metal film. The multilayer film is then patterned to form the second gate insulating film 16a from the third inorganic insulating film, and also to form the second gate electrode 17a, the gate line 17g, the light emission control line 17e, and the like from the first metal film.

Furthermore, for example, a silicon oxide film (having a thickness of about 300 nm) and a silicon nitride film (having a thickness of about 200 nm) are sequentially deposited by plasma CVD on the surface of the substrate on which the second gate insulating films 16a and the like are formed, thereby forming the first inorganic insulating film. The first inorganic insulating film, the first gate insulating film 14, and the base insulating film 12 are then patterned to form contact holes, thereby forming the first interlayer insulating film 18 and the second interlayer insulating film 19 from the first inorganic insulating film. Note that by the heat treatment performed during the formation of the first interlayer insulating film 18 and the second interlayer insulating film 19, a portion of each semiconductor layer 15a is made conductive, thus forming the source region 15aa, the drain region 15ab, and the channel region 15ac in the semiconductor layer 15a.

Subsequently, for example, a titanium film (having a thickness of about 20 nm), an aluminum film (having a thickness of about 200 nm), and a titanium film (having a thickness of about 20 nm) are sequentially deposited by sputtering on the surface of the substrate on which the second interlayer insulating film 19 is formed, thereby forming the second metal film. The second metal film is then patterned to form the source line 20f, the power supply line 20g, the source electrode 20a, the drain electrode 20b, the wiring layers 20c, 20d, and 20e, the first terminal layer 20t, and the like.

Thereafter, for example, a photosensitive polyimide resin film (having a thickness of about 2 μm) is applied onto the surface of the substrate on which the source lines 20f and the like are formed, by a spin coating method or a slit coating method. Pre-baking, exposure, development, and post-baking are then performed on the photosensitive resin film to form the first planarization film 22a.

Furthermore, for example, a titanium film (having a thickness of about 20 nm), an aluminum film (having a thickness of about 200 nm), and a titanium film (having a thickness of about 20 nm) are sequentially deposited by sputtering on the surface of the substrate on which the first planarization film 22a is formed, thereby forming the third metal film. The third metal film is then patterned to form the relay electrode 23a, the wiring layer 23b, the second terminal layer 23t, and the like.

Finally, for example, a photosensitive polyimide-based resin film (having a thickness of about 2 μm) is applied onto the surface of the substrate on which the relay electrode 23a and the like are formed, by a spin coating method or a slit coating method. Pre-baking, exposure, development, and post-baking are then performed on the photosensitive resin film to form the second planarization film 24a.

In the way described above, the TFT layer 30a can be formed.

### Organic EL Element Layer Forming Step

First, for example, an ITO film (having a thickness of about 50 nm) and a silver film (having a thickness of about 100 nm) are sequentially deposited by sputtering on the surface of the substrate on which the second planarization film 24a is formed in the above-described TFT layer forming step. The multilayer film is then patterned, for example, by wet etching using a mixed solution of phosphoric acid, nitric acid, and acetic acid, to form the reflective electrode R composed of the transparent conductive layer 31a and the metal layer 32a, and the like.

Subsequently, an inorganic insulating film, such as a silicon nitride film (having a thickness of about 100 nm), for example, is deposited by plasma CVD on the surface of the substrate on which the reflective electrode R and the like are formed, followed by patterning the inorganic insulating film to form the first edge cover 33a.

Thereafter, for example, an ITO film (having a thickness of about 100 nm) is deposited by sputtering on the surface of the substrate on which the first edge cover 33a and the like are formed. The ITO film is then patterned by, for example, wet etching using oxalic acid to form the transparent electrode 34a and the third terminal layer 34t.

Furthermore, for example, a silicon nitride film (having a thickness of about 250 nm) or the like is deposited by plasma CVD on the surface of the substrate on which the transparent electrode 34a and the like are formed, followed by patterning the silicon nitride film or the like to form the second edge cover 35a.

Subsequently, the hole injection layer 1, the hole transport layer 2, the light-emitting layer 3, the electron transport layer 4, and the electron injection layer 5, each layer having a thickness of about several tens of nanometers, i.e., about 10 nm to about 50 nm, are sequentially deposited, for example, by vacuum evaporation on the surface of the substrate on which the second edge cover 35a is formed, thereby forming the organic EL layer 36.

Finally, a transparent conductive film such as an ITO film (having a thickness of about 100 nm), for example, is deposited on the surface of the substrate on which the organic EL layer 36 is formed, by sputtering with a deposition mask, thereby forming the second electrode 37.

In the way described above, the organic EL element layer 40 can be formed.

### Sealing Film Forming Step

First, for example, a silicon nitride film (having a thickness of about 50 nm), a silicon oxynitride film (having a thickness of about 1500 nm), and a silicon oxide film (having a thickness of about 50 nm) are sequentially deposited on the surface of the substrate on which the organic EL element layer 40 is formed in the above-described organic EL element layer forming step, by plasma CVD with a deposition mask, thereby forming the first inorganic sealing film 41.

Subsequently, an organic resin such as an acrylic resin (having a thickness of about 10 μm), for example, is applied by an inkjet method onto the surface of the substrate on which the first inorganic sealing film 41 is formed, thereby forming the organic sealing film 42.

Finally, for example, a silicon nitride film (having a thickness of about 500 nm) or the like is deposited on the surface of the substrate on which the organic sealing film 42 is formed, by plasma CVD with a deposition mask to form the second inorganic sealing film 43, thus forming the sealing film 45.

In the way described above, the organic EL display device 50a can be manufactured.

As described above, in the organic EL display device 50a according to the present embodiment, the third metal film that forms the relay electrode 23a and the like of the TFT layer 30a is formed by sequentially stacking a titanium film, an aluminum film, and a titanium film. Accordingly, corrosion of the relay electrode 23a and the like, which are formed of the third metal film, due to moisture or the like, can be suppressed. Moreover, the second metal film constituting the source electrode 20a and the like of the TFT layer 30a is also formed by sequentially stacking a titanium film, an aluminum film, and a titanium film. Accordingly, corrosion of the source electrode 20a and the like, which are formed of the second metal film, due to moisture or the like, can be suppressed. Thus, the first planarization film 22a can be directly formed on the source electrode 20a and the like, and the second planarization film 24a can be directly formed on the relay electrode 23a and the like. Accordingly, the number of photomasks used to form the TFT layer 30a can be reduced.

In addition, in the organic EL display device 50a according to the present embodiment, the third metal film constituting the relay electrode 23a and the like of the TFT layer 30a is formed by sequentially stacking a titanium film, an aluminum film, and a titanium film. Accordingly, during the organic EL element layer forming step, the relay electrode 23a can be protected from an etchant by the uppermost titanium film when the multilayer film composed of the ITO film and the silver film is patterned by wet etching using a mixed solution of phosphoric acid, nitric acid, and acetic acid so as to form the reflective electrode R and the like.

### Second Embodiment

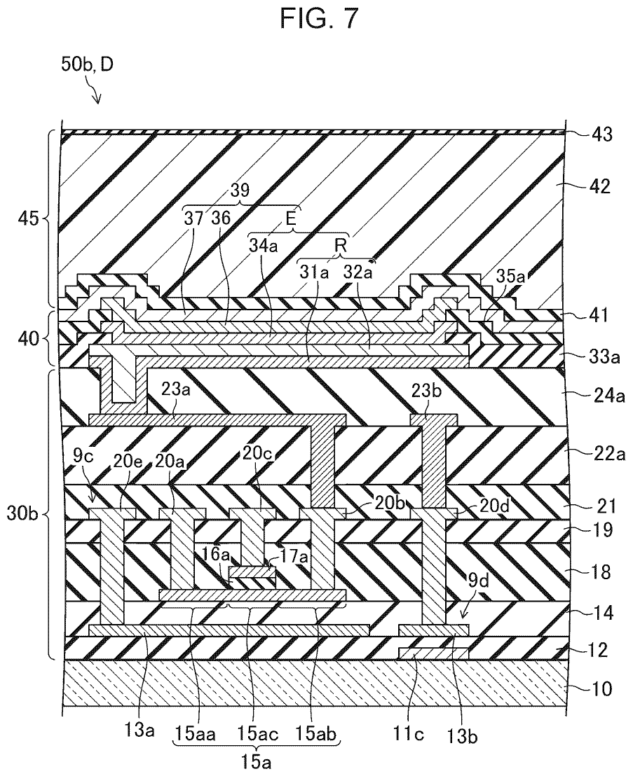

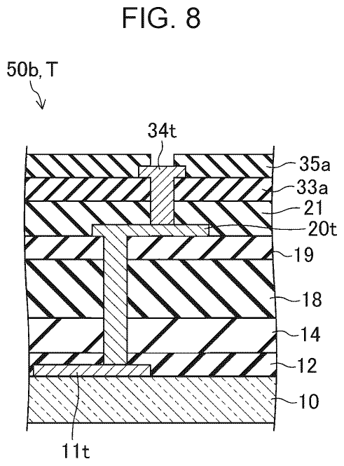

FIGS. 7 and 8 illustrate a second embodiment of a display device according to the present disclosure. Here, FIG. 7 is a cross-sectional view of a display region D of an organic EL display device 50b according to the present embodiment, corresponding to FIG. 3 described in the first embodiment described above. FIG. 8 is a cross-sectional view of a terminal portion T of the organic EL display device 50b, corresponding to FIG. 4 described in the first embodiment described above. In the following embodiments, components that are identical to those illustrated in FIGS. 1 to 6 are denoted by the same reference numerals, and a detailed description thereof is omitted.

In the first embodiment described above, the organic EL display device 50a has been exemplified in which the second metal film and the third metal film that form the TFT layer 30a are each formed of a multilayer film of Ti/Al/Ti. In the present embodiment, the organic EL display device 50b is exemplified in which the third metal film constituting the TFT layer 30b is formed of a multilayer film of Ti/Al/Ti.

As with the organic EL display device 50a of the first embodiment, the organic EL display device 50b includes, for example, the display region D provided in a rectangular shape for displaying an image, and a frame region F provided in a frame shape around the display region D and including the terminal portion T. As illustrated in FIG. 7, the organic EL display device 50b includes a glass substrate 10 provided as a base substrate, a TFT layer 30b provided on the glass substrate 10, an organic EL element layer 40 provided as a light-emitting element layer on the TFT layer 30b, and a sealing film 45 provided on the organic EL element layer 40.

As illustrated in FIG. 7, the TFT layer 30b includes a plurality of first TFTs 9a (see FIG. 5), a plurality of second TFTs 9b (see FIG. 5), a plurality of third TFTs 9c, and a plurality of capacitors 9d, all of which are provided on the glass substrate 10, as well as a third interlayer insulating film 21, a first planarization film 22a, and a second planarization film 24a, which are sequentially provided over the respective first TFTs 9a, the respective second TFTs 9b, the respective third TFTs 9c, and the respective capacitors 9d.

As illustrated in FIG. 7, the TFT layer 30b has a fourth metal film, a base insulating film 12, a fifth metal film, a first gate insulating film 14, a semiconductor film, a second gate insulating film (third inorganic insulating film) 16a, a first metal film, a first interlayer insulating film (first inorganic insulating film) 18, a second interlayer insulating film (first inorganic insulating film) 19, a second metal film, a third interlayer insulating film (second inorganic insulating film) 21, a first planarization film (first organic insulating film) 22a, a third metal film, and a second planarization film (second organic insulating film) 24a, all of which are sequentially stacked on the glass substrate 10. The fourth metal film forms a first capacitor electrode 11c and the like. The fifth metal film forms a first gate electrode 13a and the like. The semiconductor film forms a semiconductor layer 15a or the like. The first metal film forms a second gate electrode 17a and the like. The second metal film forms a source electrode 20a and the like. The third metal film forms a relay electrode 23a and the like. Here, as with the base insulating film 12, the first gate insulating film 14, the second gate insulating film 16a, the first interlayer insulating film 18, and the second interlayer insulating film 19, the third interlayer insulating film 21 is formed of, for example, a single-layer film made of an inorganic insulating film such as a silicon nitride film, a silicon oxide film, or a silicon oxynitride film, or a multilayer film thereof. The second metal film is formed of, for example, a copper-based metal film. The third metal film is formed by sequentially stacking, for example, a titanium-based metal film made of titanium or a titanium alloy, an aluminum-based metal film made of aluminum or an aluminum alloy, and another titanium-based metal film made of titanium or a titanium alloy.

As with the TFT layer 30a of the first embodiment described above, the TFT layer 30b is provided with a plurality of gate lines 17g, a plurality of light emission control lines 17e, a plurality of source lines 20f, and a plurality of power supply lines 20g.

As with the organic EL display device 50a of the first embodiment described above, the organic EL display device 50b includes a plurality of first terminal layers 20t (see FIG. 8) at the terminal portion T in the frame region F, the first terminal layers 20t being arranged along the extending direction of the terminal portion T and formed of the second metal film. Here, as illustrated in FIG. 8, in the organic EL display device 50b, neither the first planarization film 22a nor the second planarization film 24a is provided in the terminal portion T.

As illustrated in FIG. 8, the first terminal layer 20t is electrically connected to the third terminal layer 34t through a contact hole formed in the third interlayer insulating film 21, the second planarization film 24a, and the first edge cover 33a. Here, as illustrated in FIG. 8, at the terminal portion T, the third interlayer insulating film 21, the first edge cover 33a, and the second edge cover 35a may be sequentially stacked on the first terminal layer 20t, with the peripheral edge portion of the third terminal layer 34t covered with the second edge cover 35a, allowing a part of the third terminal layer 34t to be exposed from the second edge cover 35a.

In the organic EL display device 50b with the above-described configuration, as in the organic EL display device 50a of the first embodiment, the light-emitting layer 3 of the organic EL layer 36 of the organic EL element 39 is caused to emit light as appropriate through the first TFT 9a, the second TFT 9b, and the third TFT 9c in each subpixel P, thereby performing image display.

Next, a description will be given of a method for manufacturing the organic EL display device 50b of the present embodiment. Note that the method for manufacturing the organic EL display device 50b of the present embodiment includes a TFT layer forming step, an organic EL element layer forming step, and a sealing film forming step. However, the organic EL element layer forming step and the sealing film forming step of the present embodiment are substantially the same as those in the method for manufacturing the organic EL display device 50a of the first embodiment described above, and thus the present embodiment will focus mainly on the TFT layer forming step.

First, in the present embodiment, in the TFT layer forming step corresponding to that of the method for manufacturing the organic EL display device 50a described in the first embodiment, for example, a titanium film (having a thickness of about 20 nm) and a copper film (having a thickness of about 300 nm) are sequentially deposited by sputtering on the surface of the substrate on which the second interlayer insulating film 19 is formed, thereby forming a second metal film, followed by patterning the second metal film to form the source lines 20f and the like.

Subsequently, for example, a silicon nitride film (having a thickness of about 100 nm) and a silicon oxide film (having a thickness of about 200 nm) are sequentially deposited by plasma CVD on the surface of the substrate on which the source lines 20f and the like are formed, thereby forming a second inorganic insulating film, followed by patterning of the second inorganic insulating film to form the third interlayer insulating film 21.

Thereafter, for example, a photosensitive resin film made of a polyimide-based material (having a thickness of about 2 μm) is applied by a spin coating method or a slit coating method on the surface of the substrate on which the third interlayer insulating film 21 is formed. Pre-baking, exposure, development, and post-baking are then performed on the photosensitive resin film to form the first planarization film 22a.

Further, for example, a titanium film (having a thickness of about 20 nm), an aluminum film (having a thickness of about 200 nm), and a titanium film (having a thickness of about 20 nm) are sequentially deposited by sputtering on the surface of the substrate on which the first planarization film 22a is formed, thereby forming a third metal film, followed by patterning of the third metal film to form the relay electrode 23a, wiring layer 23b, and the like.

Finally, for example, a photosensitive polyimide-based resin film (having a thickness of about 2 μm) is applied onto the surface of the substrate on which the relay electrode 23a and the like are formed, by a spin coating method or a slit coating method. Pre-baking, exposure, development, and post-baking are then performed on the photosensitive resin film to form the second planarization film 24a.

In the way described above, the TFT layer 30b can be formed. Subsequently, the organic EL display device 50b of the present embodiment can be manufactured by performing the organic EL element layer forming step and the sealing film forming step in the same way as in the first embodiment described above.

As described above, in the organic EL display device 50b according to the present embodiment, the third metal film that constitutes the relay electrode 23a and the like of the TFT layer 30b is formed by sequentially stacking a titanium film, an aluminum film, and a titanium film. Accordingly, corrosion of the relay electrode 23a and the like, which are formed of the third metal film, due to moisture or the like, can be suppressed. Thus, the second planarization film 24a can be directly formed on the relay electrode 23a and the like. Accordingly, the number of photomasks used to form the TFT layer 30b can be reduced.

In addition, in the organic EL display device 50b according to the present embodiment, the third metal film constituting the relay electrode 23a and the like of the TFT layer 30b is formed by sequentially stacking a titanium film, an aluminum film, and a titanium film. Accordingly, during the organic EL element layer forming step, the relay electrode 23a can be protected from an etchant by the uppermost titanium film when the multilayer film composed of the ITO film and the silver film is patterned by wet etching using a mixed solution of phosphoric acid, nitric acid, and acetic acid so as to form the reflective electrode R and the like.

### Other Embodiments

In the respective embodiments described above, the organic EL layer has been exemplified which has a five-layer structure including the hole injection layer, the hole transport layer, the light-emitting layer, the electron transport layer, and the electron injection layer. However, the organic EL layer may also have, for example, a three-layer structure including a hole injection and transport layer, a light-emitting layer, and an electron transport and injection layer.

In the respective embodiments described above, the organic EL display device has been exemplified in which the first electrode serves as the anode and the second electrode serves as the cathode. However, the present disclosure is also applicable to an organic EL display device in which the multilayer structure of the organic EL layer is reversed such that the first electrode serves as the cathode and the second electrode serves as the anode.

In the respective embodiments described above, the organic EL display device has been exemplified in which the electrode of the TFT connected to the first electrode serves as a drain electrode. However, the present disclosure is also applicable to an organic EL display device in which the electrode of the TFT connected to the first electrode is referred to as a source electrode.

In the respective embodiments described above, the organic EL display device has been explained as an example of the display device. However, the present disclosure is also applicable to a display device including a plurality of light-emitting elements driven by current, such as a display device including quantum-dot light emitting diodes (QLEDs) having light-emitting elements that employ quantum dot-containing layers.

As described above, the present disclosure is useful for self-emissive display devices.

The present disclosure contains subject matter related to that disclosed in Japanese Priority Patent Application JP 2025-018157 filed in the Japan Patent Office on Feb. 6, 2025, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
a base substrate;
a thin film transistor layer provided on the base substrate, the thin film transistor layer including a first metal film, a first inorganic insulating film, a second metal film, a first organic insulating film, a third metal film, and a second organic insulating film that are sequentially stacked; and
a light-emitting element layer provided on the thin film transistor layer, wherein
the third metal film includes a titanium-based metal film, an aluminum-based metal film, and a titanium-based metal film that are sequentially stacked.

2. The display device according to claim 1, wherein
the second metal film includes a titanium-based metal film, an aluminum-based metal film, and a titanium-based metal film that are sequentially stacked.

3. The display device according to claim 2, wherein
the light-emitting element layer includes a plurality of first electrodes, a plurality of light-emitting functional layers, and a common second electrode that are sequentially stacked, corresponding to a plurality of subpixels constituting a display region,
each of the plurality of first electrodes includes a reflective electrode provided on the second organic insulating film and a transparent electrode provided on the reflective electrode,
a frame region is provided around the display region,
a terminal portion is provided at an end portion of the frame region,
a first terminal layer formed of the second metal film is provided at the terminal portion,
the first terminal layer is covered with a second terminal layer formed of the third metal film, and
the second terminal layer is electrically connected to a third terminal layer formed of the same material and in the same layer as the transparent electrode.

4. The display device according to claim 3, wherein
the light-emitting element layer is provided with a first edge cover covering a peripheral edge portion of the reflective electrode and a second edge cover covering a peripheral edge portion of the transparent electrode,
in the terminal portion, the second organic insulating film, the first edge cover, and the second edge cover are sequentially stacked on the second terminal layer, and
a portion of the third terminal layer is provided to be exposed from the second edge cover.

5. The display device according to claim 1, wherein
the second metal film includes a copper-based metal film, and
a second inorganic insulating film is provided between the second metal film and the first organic insulating film.

6. The display device according to claim 5, wherein
the light-emitting element layer includes a plurality of first electrodes, a plurality of light-emitting functional layers, and a common second electrode that are sequentially stacked, corresponding to a plurality of subpixels constituting a display region,
each of the plurality of first electrodes includes a reflective electrode provided on the second organic insulating film and a transparent electrode provided on the reflective electrode,
a frame region is provided around the display region,
a terminal portion is provided at an end portion of the frame region,
a first terminal layer formed of the second metal film is provided at the terminal portion, and
the first terminal layer is electrically connected to a third terminal layer formed of the same material and in the same layer as the transparent electrode.

7. The display device according to claim 6, wherein
the light-emitting element layer is provided with a first edge cover covering a peripheral edge portion of the reflective electrode and a second edge cover covering a peripheral edge portion of the transparent electrode,
in the terminal portion, the second inorganic insulating film, the first edge cover, and the second edge cover are sequentially stacked on the first terminal layer, and
a portion of the third terminal layer is provided to be exposed from the second edge cover.

8. The display device according to claim 1, wherein
the thin film transistor layer includes a semiconductor film, a third inorganic insulating film, the first metal film, the first inorganic insulating film, the second metal film, the first organic insulating film, the third metal film, and the second organic insulating film that are sequentially stacked, and
the thin film transistor layer has a thin film transistor disposed therein, the thin film transistor including a semiconductor layer formed of the semiconductor film; a gate electrode provided above the semiconductor layer with the third inorganic insulating film interposed therebetween and formed of the first metal film; and a source electrode and a drain electrode that are provided to be spaced apart from each other, the source electrode and the drain electrode being formed of the third metal film.

9. The display device according to claim 8, wherein
the semiconductor film includes an oxide semiconductor.

10. The display device according to claim 1, further comprising a sealing film provided on the light-emitting element layer.

11. The display device according to claim 3, wherein
at least one of the plurality of light-emitting functional layers is an organic electroluminescent layer.
